(19) United States
(12) Patent Application Publication
(10) Pub. No.: US 2026/0180572 A1
(43) Pub. Date: Jun. 25, 2026

(54) POWER ON RESET (POR) SIGNALING IN MULTI-DIE ARCHITECTURE

(71) Applicant: Altera Corporation, San Jose, CA (US)

(72) Inventors: Ping Xiao, E Palo Alto, CA (US); Alfredo De la Cruz Nogueiras, Gilroy, CA (US); Archanna Srinivasan, San Jose, CA (US); Kah Hooi Lim, Bayan Lepas (MY); Teik Wah Lim, Bayan Lepas (MY); Maneesha Yellepeddi, Los Gatos, CA (US)

(21) Appl. No.: 19/000,610

(22) Filed: Dec. 23, 2024

(51) Int. Cl. H03K 17/22; G06F 9/30

(52) U.S. Cl. CPC H03K 17/22; G06F 9/30101

(57) ABSTRACT

Integrated circuit devices, methods, and circuitry for implementing multiple power domains and/or multiple die with power on reset operations are provided. Integrated circuitry may include circuitry that controls operations after a power on reset based on merge circuitry that propagates ready status signals throughout communication circuitry. Power policies may be used herein to control the operations, as well as control isolation circuitry when a respective power domain is powered down.

### BACKGROUND

This disclosure relates to power on reset (POR) signaling between one or more dies of an integrated circuit.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Integrated circuits are found in numerous electronic devices and provide a variety of functionality. Many integrated circuits include arithmetic circuit blocks to perform arithmetic operations such as addition and multiplication, programmable logic to perform user configurable functions, memory, and the like. For example, a digital signal processing (DSP) block may supplement programmable logic circuitry in a programmable logic device, such as a field programmable gate array (FPGA). Different circuitry of an integrated circuit, like programmable logic or DSP blocks, may have different power demands. Moreover, there may be an increased interest in providing integrated circuits that include one or more die in its architecture. Technical problems may arise related to integrating the one or more dies given the differing power demands, such as increased power consumption arising from not tailoring systems design to the one or more dies and/or the differing power demands.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit device;

FIG. 2 is a block diagram of the integrated circuit device of FIG. 1 with multiple power domains of FIG. 1;

FIG. 3 is a block diagram that illustrates an example of the integrated circuit of FIG. 2 that includes multiple die;

FIG. 4 is a timing diagram that illustrates signals associated with the integrated circuit of FIG. 3 operation during and after a power on reset;

FIG. 5 is a block diagram that illustrates a second example integrated circuit 12 of FIG. 2 including multiple power domains;

FIG. 6 is a timing diagram that illustrates signals associated with the integrated circuit of FIG. 5 operation with a first register configuration;

FIG. 7 is a timing diagram that illustrates signals associated with the integrated circuit of FIG. 5 operation with a second register configuration;

FIG. 8 is a timing diagram that illustrates signals associated with the integrated circuit of FIG. 5 operation with a third register configuration;

FIG. 9 is a flow diagram of a process of operating the integrated circuit of FIGS. 3 and/or 5 according to stored power policies; and

FIG. 10 is a block diagram of a data processing system that may incorporate the integrated circuit of FIGS. 3 and/or 5.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers'specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, the term “or” is intended to be inclusive (e.g., logical OR) and not exclusive (e.g., logical XOR). In other words, the phrase A “or” B is intended to mean A, B, or both A and B.

Some integrated circuits, such as programmable logic devices, perform power on reset (POR) operations. POR operations may be used for device configuration control and managing the device during power down and during user modes. Furthermore, it may be desired for programmable logic devices to include multiple die and multiple power domains. However, integration complications may arise when adding die or power domains. For example, integrating power on reset operations in the multi-die, multidomain device is complicated, is sometimes based on per-device custom integration which is not scalable and may have a large footprint.

Systems and methods described herein may address one or more such integration complications through proposing an architecture that uses logic circuitry to merge and control signal generation, while improving an ability of power control over the integrated circuit. The proposed systems and methods also enable each die of the integrated circuit to be available for a standalone test (e.g., while isolating the die under test from the other die) while functioning the die together as a large system (e.g., integrated circuit system) post-integration into multi-die, multi-power domain. The proposed systems and methods may be scalable and/or correct-on-construction, being able to run independent of custom device integrations.

To elaborate, integration may be based on on-die power gating and clock gating based on a programmable power switch, which may be statically or dynamically controlled. The programmable power switch may be built in an intellectual property (IP) core block such as a digital signal processing block, in FPGA core fabric to power down the IP core block when it is not being used in an application. Similarly, programmable clock gating may be implemented to a trunk of a clock tree to disable the clock to save power while a circuit being driven by that clock trunk is not being used in an application. While this enables power gating, these methods correspond to relatively large footprints, higher power consumption that desired as power is used to perform the switching, and relatively large overhead in implementing the on-die and clock gating, including design effort being expended in compensating for a performance drop arising from power gating. Integration may also be based on a predefined and fixed power bump down-bond or power pin power-down. However, doing so may be based on a customized power-down scheme that is addressed and fixed in device circuit design without flexibility to change based on the application, which is limiting for use in an FPGA as FPGAs may be used in applications where flexibility may be desired.

Described herein is a proposed architecture that may be used in programmable logic devices to enable power on reset operations and to enable device partial power-down in a configurable manner for multiple dies and/or for multiple power domains. The proposed architecture includes device power partition systems and methods that may enable device partial power-down, a device configuration flow with a power policy setting before the device configuration, and a gating mechanism for final POR generation based on power-down intention. The proposed architecture may support both static and dynamic power down on any defined power island (e.g., power domain). The proposed architecture may be configurable through device configuration or through in-field device management control (e.g., via a remote terminal unit (RTU)). The proposed architecture may be scalable without a large footprint or having large amounts of design overhead. Moreover, systems and methods described herein enable a reset mode if the integrated circuit detects a power supply loss in one of multiple power supplies that supply different power domains. Systems and methods described herein relative to the proposed architecture enable a true power down state from a device power pin, which may help improve (e.g., maximize) power savings.

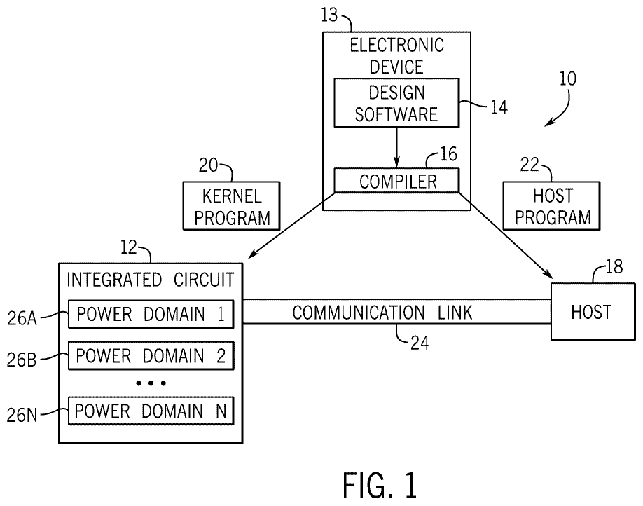

With this in mind, FIG. 1 illustrates a block diagram of a system 10 that may be used to implement the systems and methods of this disclosure on an integrated circuit system 12 (e.g., a single monolithic integrated circuit or a multi-die system of integrated circuits). A designer may desire to implement a system design to perform the operations of this disclosure on the integrated circuit system 12 (e.g., a programmable logic device such as a field-programmable gate array (FPGA) or an application-specific integrated circuit (ASIC) that includes programmable logic circuitry). The integrated circuit system 12 may include a single integrated circuit, multiple integrated circuits in a package, or multiple integrated circuits in multiple packages communicating remotely (e.g., via wires or traces). In some cases, the designer may specify a high-level program to be implemented, such as an OPENCL® program that may enable the designer to more efficiently and easily provide programming instructions to configure a set of programmable logic cells for the integrated circuit system 12 without specific knowledge of low-level hardware description languages (e.g., Verilog, very high-speed integrated circuit hardware description language (VHDL)). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit system 12.

In some systems, the programmable integrated circuit system 12 may include two or more power domains 26 (power domain 26A, power domain 26B, power domain 26N). Any number of power domains 26 may be included. Configured programmable logic may correspond to different power domains, further enhancing customization available to an operator through use of programmable logic-based systems.

In a configuration mode of the integrated circuit system 12, a designer may use an electronic device 13 (e.g., a computer) to implement high-level designs (e.g., a system user design) using design software 14, such as a version of INTEL® QUARTUS® by INTEL CORPORATION. The electronic device 13 may use the design software 14 and a compiler 16 to convert the high-level program into a lower-level description (e.g., a configuration program, a bitstream). The compiler 16 may provide machine-readable instructions representative of the high-level program to a host 18 and the integrated circuit system 12. The host 18 may receive a host program 22 that may control or be implemented by the kernel programs 20. To implement the host program 22, the host 18 may communicate instructions from the host program 22 to the integrated circuit system 12 via a communications link 24 that may include, for example, direct memory access (DMA) communications or peripheral component interconnect express (PCIe) communications. In some embodiments, the kernel programs 20 and the host 18 may configure programmable logic blocks (e.g., LABs) on the integrated circuit system 12. The programmable logic blocks (e.g., LABs) may include circuitry and/or other logic elements and may be configurable to implement a variety of functions in combination with digital signal processing (DSP) blocks.

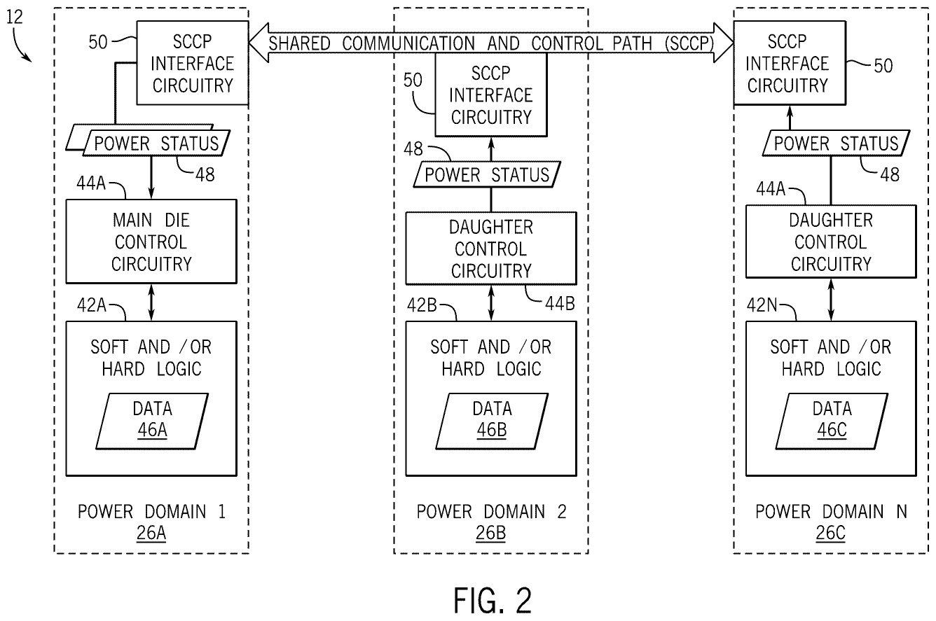

The designer may use the design software 14 to generate and/or to specify a low-level program, such as the low-level hardware description languages described above. Further, in some embodiments, the system 10 may be implemented without a separate host program 22. Thus, embodiments described herein are intended to be illustrative and not limiting. An illustrative embodiment of a programmable integrated circuit system 12 such as a programmable logic device (PLD) (e.g., a field programmable gate array (FPGA) device) that may be configurable to implement a circuit design is shown in FIG. 2.

FIG. 2 is a block diagram of the integrated circuit system 12 with multiple power domains 26. In some systems, the programmable integrated circuit system 12 may include two or more power domains 26 (power domain 26A, power domain 26B, power domain 26N). Any number of power domains 26 may be included. The one or more power domains 26 may be operated at different power levels. For example, a power management unit (PMU) may supply the different amounts of power via one or more power rails to the one or more power domains 26. This may include power gating or removing power from one or more of the power domains 26, which may reduce an overall amount of power consumed by the integrated circuit system 12.

Each power domain 26 may communicate with each other through a shared communication and control path (SCCP) 52. The power domains 26 may be associated with one or more die (not illustrated). The circuitry of the respective power domains 26 may communicate via the SCCP 52 and interface circuitry 50.

The power domains 26 may include hard and/or soft logic 42 (hard and/or soft logic 42A, hard and/or soft logic 42B, hard and/or soft logic 42C). Control circuitry 44 (control circuitry 44A, control circuitry 44B, control circuitry 44N) of each power domain 26 may control the hard and/or soft logic, which may generate data 46 (data 46A, data 46B, data 46N). Any suitable analog or digital data may be generated by the soft and/or hard logic 42.

The integrated circuit system 12 (e.g., a field-programmable gate array (FPGA) integrated circuit device) may include, in the hard and/or soft logic 42 as soft logic, a two-dimensional array of functional blocks sometimes referred to as arithmetic logic modules (ALMs), including programmable logic blocks (e.g., also referred to as logic array blocks (LABs) or configurable logic blocks (CLBs)) and other functional blocks, such as embedded digital signal processing (DSP) blocks and embedded random-access memory (RAM) blocks, for example. Functional blocks such as LABs may include smaller programmable regions (e.g., logic elements, configurable logic blocks, or adaptive logic modules) that receive input signals and perform custom functions on the input signals to produce output signals. LABs may also be grouped into larger programmable regions, sometimes referred to as logic sectors that are individually managed and configured by corresponding logic sector managers. The grouping of the programmable logic resources on the integrated circuit system 12 into logic sectors, logic array blocks, logic elements, or adaptive logic modules is merely illustrative. In general, the integrated circuit system 12 may include functional logic blocks of any suitable size and type, which may be organized in accordance with any suitable logic resource hierarchy.

The control circuitry 44 may monitor power statuses of power supplies of the respective power domains 26 and report such power statuses as power statuses 48 to the main die control circuitry 44A. The main die control circuitry 44A may gatekeep and time operations based on receipt of each power status 48 from the die. For example, the main die control circuitry 44A may wait to indicate that POR is complete until receiving completing signals from each participating die. In this way, POR operations may be enabled in a multi-power domain 26 architecture. Sometimes circuitry of FIG. 2 may be included on one or more disaggregated dies.

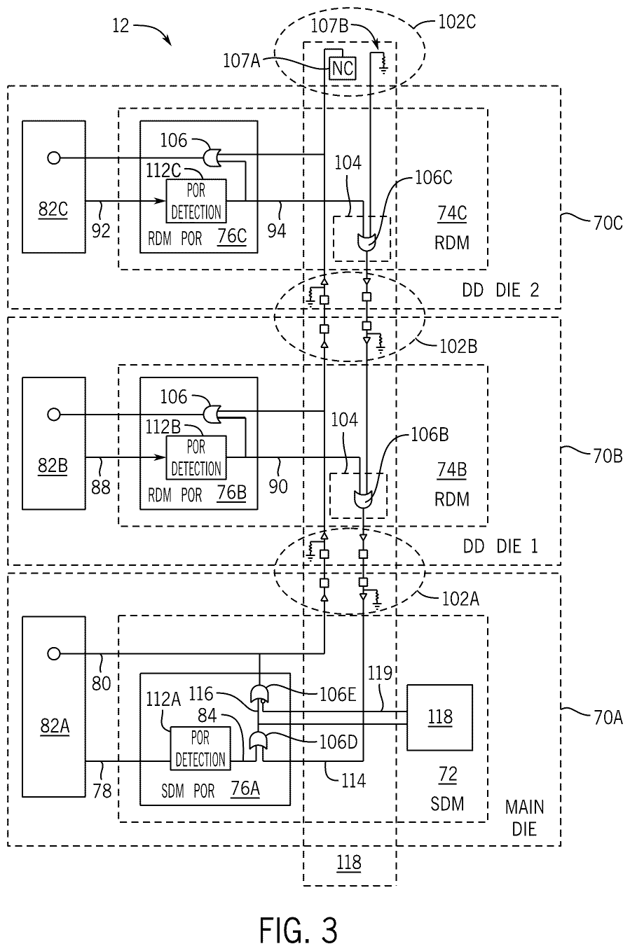

To elaborate, FIG. 3 is a block diagram that illustrates an example integrated circuit 12 that includes multiple die 70 (die 70A, die 70B, die 70C). The different die 70 may be disposed or associated with different power domains 26 of FIG. 2. The die 70A may be a main die relative to the other die. The die 70B and the die 70C may be daughter die. The die 70A may receive one or more signals from the die 70B and/or die 70C. The die 70A may generate control signals to operate the die 70B and/or die 70C to perform one or more operations based on the one or more received signals. Such signals may include the data 46 and/or the power status signals 48 of FIG. 2. For example, the die 70A may change operating bandwidth of computations performed by the die 70B based on a power status from the die 70C. Any suitable control operations may be performed relative to the die 70A and the die 70B and/or die 70C. Moreover, although three die 70 are discussed here, it should be understood that any number of die 70 may be used as daughter die or main die to implement the systems and methods described herein.

Although from a component perspective, each die 70 may include generally the same or similar control circuitries for POR operations. However, the die 70A, as the main die, may be allocated a greater proportion of on-device memory. The on-device memory may correspond to memory or storage disposed on the integrated circuit system 12, in one or more of the power domains 26, and/or accessible by control circuitry of one or more of the power domains 26. The on-device memory may be shared among one or more die 70. The main die (e.g., die 70A) may be allocated relatively greater amounts of the on-device memory as the main die operates to host the integration of the multiple dies 70 as one device.

Internally, these die 70 may be architecturally or structurally the same (e.g., same and repeated core fabric, same and repeated FPGA elements). For example, the die 70A, the die 70B, and the die 70C may have identical programmable logic and related control circuitry (e.g., FPGA cores 82) and each die may include a respective device manager (DM). This may lead to a desire to have a similar or same architecture for power on reset (POR) reporting and detection among the die 70, which may be enabled via at least a bus 100.

The FPGA core 82 may correspond to soft logic of soft and/or hard logic 42 of FIG. 2. The respective DMs may correspond to control circuitry 44 in FIG. 2.

The bus 100 may interconnect the die 70. The bus 100 may include interface circuitry 102 (e.g., interface circuitry 102A, interface circuitry 102B) between the power domains 26. Any suitable interdie communication structure may be used. For example, the bus 100 may be a portion of a configuration network-on-chip (CNOC) bus. The bus 100 may correspond to SCCP 52 in FIG. 2 and the interface circuitry 102 may correspond to SCCP interface circuitry 50 in FIG. 2. As another example, the bus 100 can be an interface that reuses one or more communication components of the integrated circuit system 12, such as a network-on-chip. The interface circuitry 102 may correspond to a subset of components of a CNOC bus. The interface circuitry 102 and 102B include intercoupled pins that are coupled to ground as well as buffer circuitry at each pin. The bus 100 may include the communication paths (not illustrated) to transmit data and/or control signals among between the FPGA cores 82. The bus 100 may include logic circuitry 104. In this example, the logic circuitry 104 includes OR gates 106 (OR gate 106B, OR gate 106C). The logic circuitry 104 (and other logic circuitry describe herein) should be understood may include any suitable combination of AND gates, Not OR gates, OR gates, Not AND gates, inverters, XOR gates, or the like. The bus 100 may, based on the logic circuitry 104, merge respective power on signals during propagation to condense the respective signals into one bit.

The integrated circuit system 12 may also include die-to-die connection IO buffers and pads and/or bumps as interface circuitry 102A and 102B. The edge die 70C may include edge interface circuitry 102C components, such as termination portions at die edge. Edge interface circuitry 102C may have relatively weak pull-down to ground at input terminations to the integrated circuit system 12. The edge interface circuitry 102C, as illustrated, includes an input pin 107A coupling to ground and an input pin 107B not coupled to anything (e.g., floating). The edge interface circuitry 102C may operate as die edge termination circuitry. The last of the daughter die 70C may include the edge interface circuitry 102C at a physical edge of its die and/or of the integrated circuit system 12. Any number of daughter die 70 (e.g., die 70B, die 70C) may be coupled to a main die 70A as long as a last daughter die 70C coupled to the bus 100 is terminated with edge interface circuitry 102C.

Post-integration of the disaggregated die 70, each part of programmable logic resource (e.g., each respective FPGA core 82) in each die 70, in term of resource merging of FPGA fabric, is to be powered on and ready before operations post-reset may proceed. In terms of POR detection, each die 70 detects power supplied to its corresponding programmable logic fabric without detecting power supplies to other programmable logic fabric of other die 70, and reports power status signals to the other die 70. The die 70 may intercommunicate power status signals (e.g., POR_FPGA_md status on path 84, POR_FPGA_dd1 status on path 90, POR_FPGA_dd2 status on path 94) via a bus 100 as part of power on reset operations, where the power status signals may indicate power is supplied to the respective FPGA cores 82 after a power on reset operation. Once programmable logic of each die 70 is powered, the die 70A may trigger further post-reset operations, such as programmable logic configurations.

To elaborate, each device manager may be configurable into a secure device manager (SDM) 72 operation or a remote device manager (RDM) 74 operation. The die 70A may include a SDM 72 as a main die. The die 70B and 70C may include respective RDM 74 (RDM 74B, RDM 74C). Each DM may include power on reset detection circuit (POR) 76 (POR 76A, POR 76B, POR 76C). The die 70B and the die 70C may include remote device managers (RDMs) 74 (RDM 74B, RDM 74C). The RDM 74 circuitry may be structurally identical to the SDM 72 circuitry and differ in configurations applied that change operations of the respective blocks. The RDMs 74 may respectively include the power on reset detection circuit (POR) 76B and 76C.

The POR 76 may include analog circuitry to detect power supplied to corresponding programmable logic, such as FPGA cores 82 (FPGA core 82A, FPGA core 82B, FPGA core 82C). The FPGA cores 82 may be separate portions of programmable logic circuitry. The FPGA cores 82 may include identical structures used as respective programmable logic circuitry and may be disposed separately of each other among the power domains 26. The FPGA cores 82 may transmit data and/or control signals among each other via communication paths (not illustrated). As separate portions of programmable logic circuitry, the FPGA cores 82 receive power from different power rails and distribution circuitry. Moreover, as the die 70 may be in different power domains, the FPGA cores 82 may receive different amounts of power, such as part of a power-gating operation.

It is noted that in the examples described herein, an active high (logic “1”) voltage level is used to indicate “in reset” and a logic low (“0”) voltage level is used to indicate “out of reset.” In some systems, the values may be reversed and a “1” voltage level may be used to indicate “out of reset” or ready and the “0” voltage level may be used to indicate “in reset” or not ready. Each of the DMs (e.g., SDM 72 and RDM 74, described below, via corresponding POR 76 reporting) may, in this example, report via bus 100 a “1” voltage level while their respective FPGA cores 82 are not ready after a power on reset and change to a “0” voltage level once ready and powered. Due to the OR gate 106 interconnections in the die 70, as long as one FPGA core 82 is not ready (e.g., respective DM reporting a “1”), the die 70A does not report as ready after power on reset as it still receives a “1” voltage level reported. Once each FPGA core 82 is ready (e.g., analog voltage determined to be greater than or equal to threshold voltage), and the respective PORs 76 report the readiness (e.g., with logic “0” digital signals), the die 70A continues with post-reset operations, such as configuration of programmable logic of FPGA cores 82.

Each POR 76 may include POR detector 112 (POR detector 112A, POR detector 112B, POR detector 112C). Power signals sent from the FPGA cores 82 to respective DMs to indicate whether the programmable logic is powered may be analog voltages. Each POR 76 may receive the analog voltages at the POR detector 112. The POR detector 112 may include analog circuitry to detect when its respectively received analog voltage (e.g., received via path 78, 88, 92, respectively) crosses a threshold voltage. The analog circuitry may include sense amplifiers, voltage comparators, or other suitable circuitry to compare the received analog voltage to a threshold voltage level to determine when the analog voltage is reporting suitable power on voltage. Different threshold voltage levels may be used by different POR 76 based on configurations of power domains 26 that respective die 70 and/or FPGA core 82 are disposed. In some integrated circuit systems 12, the different power domains 26 powered to different post-reset voltage levels.

For example, the SDM 72 includes POR 76A. The POR 76A may detect whether power is provided to the die 70A such that the FPGA core 82A is powered based on main die FPGA core function domain powers signals via path 78. While the FPGA core 82A is underpowered, the POR 76A may report a “1” as its power status (e.g., POR_FPGA_md status bit of “1” on path 84). When the FPGA core 82A is suitably powered, the POR 76A may report a “0” as its power status (e.g., POR_FPGA_md status bit of “0” on path 84). The RDM 74B includes POR 76B. The POR 76B may detect whether power is provided to the die 70B such that the FPGA core 82B is powered based on daughter die (DD) FPGA core function domain powers signals via path 88. While the FPGA core 82B is underpowered, the POR 76B may report a “1” as its power status (e.g., POR_FPGA_dd1 status bit of “1” on path 90). When the FPGA core 82B is suitably powered, the POR 76B may report a “0” as its power status (e.g., POR_FPGA_dd1 status bit of “0” on path 90). Moreover, the RDM 74C includes POR 76C. The POR 76C may detect whether power is provided to the die 70C such that the FPGA core 82C is powered based on DD FPGA core function domain powers signals via path 92. While the FPGA core 82C is underpowered, the POR 76C may report a “1” as its power status (e.g., POR_FPGA_dd2 status bit of “1” on path 94). When the FPGA core 82C is suitably powered, the POR 76C may report a “0” as its power status (e.g., POR_FPGA_dd2 status bit of “0” on path 94).

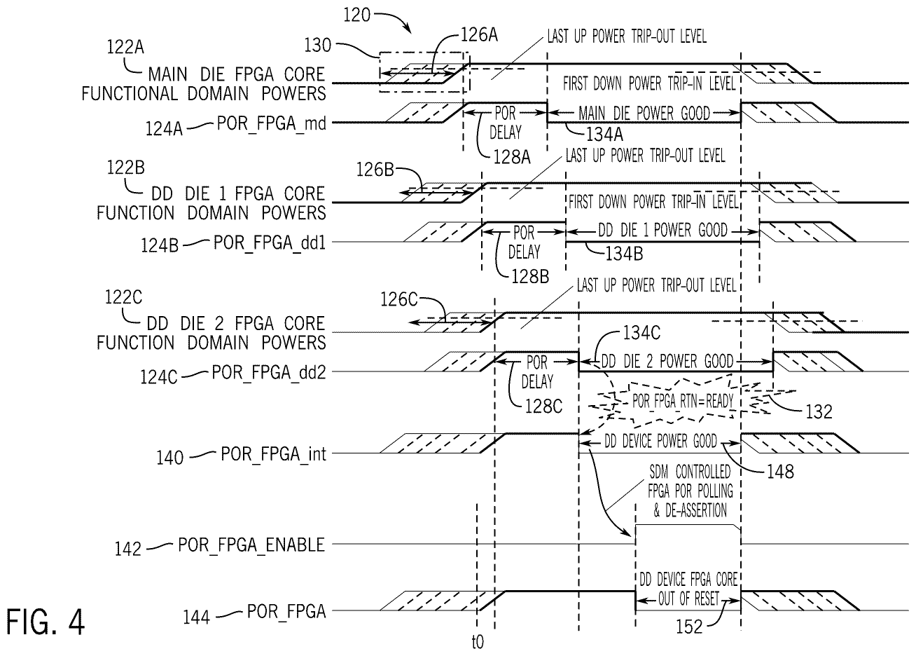

The bus 100 may transmit a POR_FPGA signal generated in SDM POR 76A to each of the other POR destinations (e.g., POR 76B, POR 76C) across the integrated circuit system 12. As the POR_FPGA signals propagate throughout the bus, the POR_FPGA signals are merged into a POR_FPGA return status bit (e.g., a POR_FPGA_RTN signal on bus 114). The logic circuitry 104 may merge the power signals in route for returned reporting to the SDM 72, and by merging the POR_FPG_RTN signal on bus 114 may be logic high “1” until each of the FPGA cores 82 are ready to proceed (e.g., signalling “0” from the respective DMs). For example, the logic gate 106C outputs a “1” bit until receiving both “0” bits at its inputs, at which point would generate a “0” bit, merging both inputs into one ready output. As another example, the logic gate 106B receives, at its respective inputs, a merged output from the logic gate 106C (e.g., POR_FPGA_dd1 merged with a “0” voltage from ground) and POR_FPGA_dd1 via path 90, and thus the logic gate 106B generates a “0” bit when both its inputs receive “0” bits. In this way, the logic gate 106B merges POR_FPGA_dd1 reporting with POR_FPGA_dd2 reporting before sending a status of both to SDM 72. This example operation is illustrated further in FIG. 4.

To elaborate on operation, FIG. 4 is a timing diagram 120 of disaggregated die (DD) integrated circuit system 12 operation during and after a power on reset. FIGS. 3 and 4 are described together herein for ease of description. Certain signals are described herein to emphasize some aspects of power on reset operations. It should be understood that additional alternative signaling operations may be included or also performed when performing power on reset operations. As noted above, an active high (logic “1”) voltage level may be used to indicate “in reset” and a logic low (“0”) voltage level may be used to indicate “out of reset.” For ease of explanation, signal names from FIG. 3 are included on the timing diagram and are labelled with reference numerals to help understanding. For example, FPGA core 82 power status signals, that generally indicate that a respective FPGA core is powered and ready for further operation, are signals 122 (signal 122A, signal 122B, signal 122C) in timing diagram 120. For example, POR 76 responsive power reporting signals correspond to signals 124 (e.g., signal 124A, signal 124B, signal 124C).

Each POR 76 detects its FPGA core 82 being powered on (e.g., suitable voltage level of signal 122) and, once ready, drives its respective signal 124 to a ready voltage level (e.g., “0” in this example”). Variability in readiness and timing is illustrated via signal edge variability illustrations, such as illustration 130. Once each signal 124 is ready (“0” voltage level) signal POR_FPGA_int from logic gate 106D is output with the ready voltage level (e.g., “0” in this example), as illustrated with illustration 132.

To elaborate on this, POR 76A may detect the FPGA core 82A being powered based on a voltage received as the FPGA core functional domain powers signal on path 78 (shown as signal 122A). Time period 126A may correspond to a powering time period that the FPGA core 82A analog voltage is not ready yet (e.g., as indicated via voltage received as the FPGA core functional domain powers signal via path 78, shown as signal 122A). Delay associated with POR 76A detecting the suitable voltage level and changing a value of the POR_FPGA_md signal (e.g., signal 124A) corresponds to a time period 128A. The POR 76A outputs a bit (e.g., “0” bit voltage level) when the signal 122A has a suitable analog voltage level to continue operation after power on reset, which may be configurable via memory accessible by the POR 76A. Indeed, when the FPGA core 82A is powered to a threshold analog voltage level, the POR 76A may generate POR_FPGA_md via path 84 as a logic low voltage (shown as signal 124A). Driving POR_FPGA_md via path 84 to a logic low voltage corresponds to time period 134A.

POR 76B may detect the FPGA core 82B being powered based on a voltage received as the FPGA core functional domain powers signal on path 88 (shown as signal 122B). Time period 126B may correspond to a powering time period that the FPGA core 82B analog voltage is not ready yet (e.g., as indicated via voltage received as the FPGA core functional domain powers signal via path 88, shown as signal 122B). Delay associated with POR 76B detecting the suitable voltage level and changing a value of the POR_FPGA_dd1 signal (e.g., signal 124B) corresponds to a time period 128B. The POR 76B outputs a bit (e.g., “0” bit voltage level) when the signal 122B has a suitable analog voltage level to continue operation after power on reset, which may be configurable via memory accessible by the POR 76B. Indeed, when the FPGA core 82B is powered to a threshold analog voltage level, the POR 76B may generate POR_FPGA_dd1 via path 90 as a logic low voltage (shown as signal 124B). Driving POR_FPGA_dd1 via path 90 to a logic low voltage corresponds to time period 134B.

POR 76C may detect the FPGA core 82C being powered based on a voltage received as the FPGA core functional domain powers signal on path 92 (shown as signal 122C). Time period 126C may correspond to a powering time period that the FPGA core 82C analog voltage is not ready yet (e.g., as indicated via voltage received as the FPGA core functional domain powers signal via path 92, shown as signal 122C). Delay associated with POR 76C detecting the suitable voltage level and changing a value of the POR_FPGA_dd2 signal (e.g., signal 124C) corresponds to a time period 128C. The POR 76C outputs a bit (e.g., “0” bit voltage level) when the signal 122C has a suitable analog voltage level to continue operation after power on reset, which may be configurable via memory accessible by the POR 76C. Indeed, when the FPGA core 82C is powered to a threshold analog voltage level, the POR 76C may generate POR_FPGA_dd2 via path 94 as a logic low voltage (shown as signal 124C). Driving POR_FPGA_dd2 via path 94 to a logic low voltage corresponds to time period 134C.

When each FPGA core 82 is ready, the POR_FPGA_RTN signal from logic gate 106B is a ready voltage (here, “0” voltage level). This ready voltage is provided as an input to logic gate 106D. When the logic gate 106D receives “0” voltages as inputs, the logic gate 106D generates POR_FPGA_int signal 140 (“POR_FPGA_int” on path 116 in FIG. 3) to indicate that the FPGA cores 82 are ready after power on reset. Time period 148 corresponds to POR_FPGA_int signal 140 being transmitted as a ready voltage level (e.g., “0” voltage level). POR logic gate 106E receives the POR_FPGA_int signal 140 and an enable signal, POR_FPGA_Enable signal 142, from control circuitry 118 of the SDM 72 (e.g., “POR_FPGA_Enable signal” on path 119 in FIG. 3). The control circuitry 118 may poll path 116 to identify when POR_FPGA_int signal is on the path 116 and indicating ready. It is noted that control circuitry 118 may include a microcontroller core with BootROM that may poll the POR_FPGA_int signal 140 and control, via firmware of BootRom, a deassertion of the POR_FPGA signal 144 that is distributed through the bus 100 to each the FPGA core 82 destinations.

The POR_FPGA_Enable signal 142 may be low when sent by the control circuitry 118. While “0”, The POR_FPGA_Enable signal 142 may disable the POR_FPGA signal 144, which cause a reset state while POR_FPGA signal 144 equals logic high, “1”, voltage. The POR_FPGA_Enable signal 142 being a “1” voltage may enable the POR_FPGA signal 144, which sets the POR_FPGA signal 144 to POR_FPGA_int signal 140. At power on, the control circuitry may set the signal POR_FPGA_Enable signal 142 to zero, putting the FPGA core 82 into a reset state, regardless of the status of POR_FPGA_int signal 140. Once the control circuitry 118 identifies POR_FPGA_int is ready (e.g., with the falling edge from “1” to “0”) through polling, the control circuitry sets POR_FPGA_Enable signal 142 to “1” to cause POR_FPGA to equal POR_FPGA_int=0, which may take the FPGA_core 82 out of reset. The firmware polling in the control circuitry 118 together with the OR gate 106E may implement the function of hardware assertion (e.g., from “0” to “1”) and firmware de-assertion (e.g., from “1” to “0”) on the FPGA core 82 POR signal POR_FPGA 144.

The POR_FPGA_Enable signal 142 may be enabled (e.g., at time, t0) before receiving a ready signal from the logic gate 106B, such that the response of the SDM 72 may be relatively faster with the enable signal waiting at logic gate 106E to trigger operation when ready. When the high voltage of POR_FPGA_Enable signal 142 (e.g., received at an inverted terminal of logic gate 106E) and the low voltage of the POR_FPGA_int signal 140 are received at logic gate 106E, such as during time period 150, the logic gate 106E may generate a logic low voltage output as “POR_FPGA” on path 80 (e.g., during time period 152) to each FPGA core 82 circuitry to signal that operation may continue after power on reset. The POR_FPGA_Enable signal 142 may be deasserted by control circuitry 118 to implement a firmware controlled FPGA core 82 POR assertion regardless of the power status of the FPGA core 82 on the POR_FPGA_int from the POR detector.

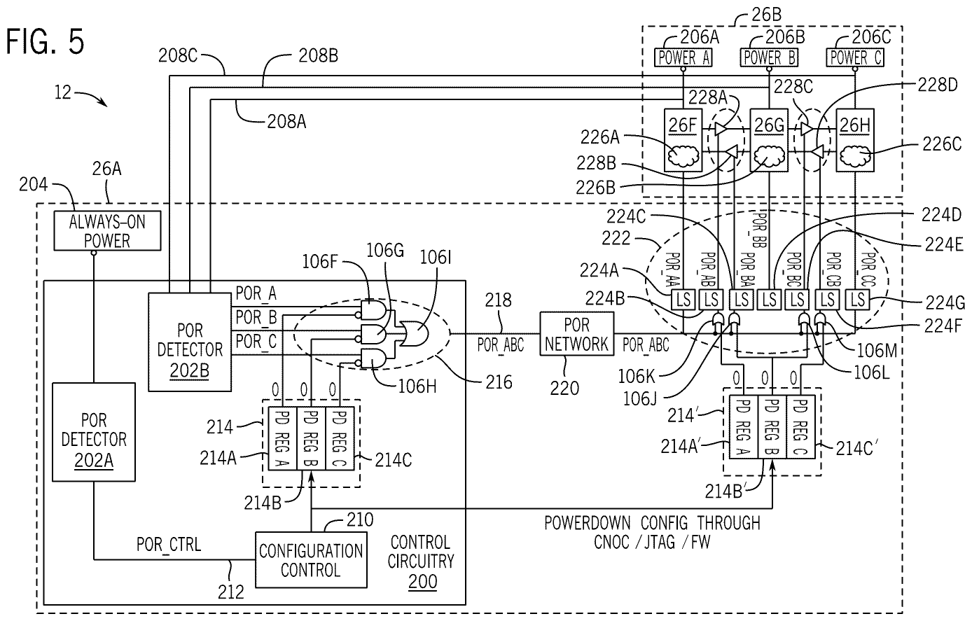

With the foregoing in mind, FIGS. 5-9 discuss the integrated circuit system 12 that may detect a state of each power supply of each domain 26 and, based on the states, enable device initialization and configuration when each power supply are up. The integrated circuit system 12 may continue to monitor the power while operated in a user mode. Should any of the power supplies be removed, control circuitry may set the integrated circuit system 12 to a reset mode. With the integrated circuit system 12 performance, capacity, and increased complexity, to maintain a performance target, the integrated circuit system 12 power management systems and methods, such as partial static and dynamic power-down, becomes more and more important to ease the issue of power reduction when a power is not being used. Thus, it may be desired to integrate power management operations, power on reset operations, and power domain isolation operations into disaggregated, multi-die applications.

FIG. 5 is a block diagram illustrating an example integrated circuit system 12 of FIG. 1 including multiple power domains 26 (power domain 26F, power domain 26G, power domain 26H).

The power domains 26 may be supplied by different amounts of power at different times during operation of the integrated circuit system 12. For example, to reduce a total amount of power consumed by the integrated circuit system 12 while operating, the integrated circuit system 12 sometimes be operated into different power modes, including a power gated mode. During some of the power modes, power may be removed from some power domains 26 or power may continue to be supplied to one or more power domains 26. For example, the power domain 26A may be an always on power domain. The power domain 26B may be user function power domain. As an always on power domain, the power domain 26A may receive power even when the integrated circuit system 12 is operated in a power gated mode. The power domain 26B may be decoupled from a power supply at some time as part of the integrated circuit system 12 being operated in the power gate mode.

The power domain 26A may include control circuitry 200. The control circuitry 200 may be the SDM 72 of FIG. 3. The power domain 26F, power domain 26G, and power domain 26H may include respective control circuitry (not illustrated) that corresponds to RDM 74 of FIG. 3. In this way, power on reset (POR) may be signaled to the control circuitry (e.g., control circuitry 200), which may operate responsive to one or more power on reset voltages (e.g., POR_FPGA_int on path 116). The control circuitry 200 may be disposed on or integrated into a die (not illustrated), which may correspond to other die 70 described herein and thus may include one or more components described herein to enable management of power on reset operations among multiple die 70. The control circuitry 200 may control power on reset and configuration operations of the integrated circuit system 12.

The control circuitry 200 may include one or more power on reset (POR) detectors 202 (POR detector 202A, POR detector 202B). The POR detector 202A may detect power supplied through a coupling at a pin to an always-on power supply 204. The POR detector 202B may detect user domain power supplies 206 (power supply 206A, power supply 206B, and power supply 206C) via paths 208 (path 208A, path 208B, path 208C). The POR detector 202A may generate, based on the always-on power from power supply 204, a POR control signal (POR_CTRL). The POR_CTRL signal may be transmitted via path 212 to configuration control circuitry 210. The configuration control circuitry 210 may program the integrated circuit based on the POR_CTRL signal. In particular, the configuration control circuitry 210 may instruct one or more portions of the integrated circuit system 12 out of a power on reset (POR) mode.

An array of power down (PD) registers 214 (register 214A, register 214B, register 214C) may be disposed in the always-on power domain 26A. The registers 214 may store the power policy of the integrated circuit system 12. The registers 214 may power up to a default power supply. The always-on power domain 26A may also include an array of replicated PD registers 214′ (register 214A′, register 214B′, register 214C′). When a power domain 26 is powered up, the registers 214 may output a logic low voltage (e.g., “0” voltage level) and the registers 214′ may be operated to mirror the values stored in the registers 214. The registers 214′ may store the power policy on behalf of the power domain 26B, such that power policy states are not lost in the registers 214′ when the supply of power is adjusted or removed for the power domain 26B. For example, the registers 214′ storing a logic high voltage (e.g., “1” voltage level) may indicate that the power domain 26F powered by the power supply 206A is set to power down.

POR logic circuitry 216 may include logic gates 106 (logic gate 106F, logic gate 106G, logic gate 106H, logic gate 106I). The POR logic circuitry 216 may execute the power policy of the integrated circuit system 12 stored in the registers 214. The logic gates 106 output may merge or condense into a signal POR_ABC on path 218 received and distributed by a POR network 220. A POR network 220 may include circuitry to propagate the POR_ABC output from the POR logic circuitry 216 to downstream logic circuitry 222 coupled to user function power domain 26B. The downstream logic circuitry 222 includes logic gate 106J, logic gate 106K, logic gate 106L, and logic gate 106M and level shifters (LS) 224 (LS 224A, LS 224B, LS 224C, LS 224D, LS 224E, LS 224F, and LS 224G). The downstream logic circuitry 222 may implement the power policy on the user function power domain 26B. For example, the downstream logic circuitry 222 may implement the power policy stored in the registers 214′ in one or more power domains 26 (power domain 26F, power domain 26G, power domain 26H) user functions or user designed circuitry 226 (circuitry 226A, circuitry 226B, circuitry 226C) is implemented in programmable logic within.

The user function power domain 26B may include one or more power domains 26F, 26G, 26H, which may be associated with components disposed on one or more die. For example, a die may include the power domains 26F and 26G and a second die (not illustrated) may include the power domain 26H, where both die correspond to daughter die from main die of the power on domain 26A.

The POR_ABC signal received at the logic circuitry 222 from the POR network 220 may be propagated through LS 224A to the power domain 26F as POR_AA signal. In response to the POR_AA signal, circuitry 226A may exit a POR operation and continue operation according to one or more user configurations and/or a normal device operation. The POR_ABC signal received at the logic circuitry 222 from the POR network 220 may be propagated through LS 224D to the power domain 26G as POR_BB signal. In response to the POR_BB signal, circuitry 226B may exit a POR operation and continue operation according to one or more user configurations and/or a normal device operation. The POR_ABC signal received at the logic circuitry 222 from the POR network 220 may be propagated through LS 224G to the power domain 26H as POR_CC signal. In response to the POR_CC signal, circuitry 226C may exit a POR operation and continue operation according to one or more user configurations and/or a normal device operation.

The POR_ABC signal received at the logic circuitry 222 from the POR network 220 may be propagated through to logic gate 106J. As long at least one of the POR_ABC signal or the register 214A′ signal is a logic level high (e.g., “1” voltage level), the logic gate 106J outputs a logic high level (e.g., “1” voltage level) to level shifter 224B. For example, the POR_ABC signal on path 218 having a logic high level (e.g., “1” voltage level) may indicate that power domain 26B is not ready yet based on POR detection. The level shifter 224B may generate a POR_AB signal, which may be transmitted to buffer 228A as a disable signal to disable the buffer 228A (e.g., stopping signals from crossing into adjacent power domain). In response to the POR_AB signal from the buffer 228A, circuitry 226B may undergo a power on reset operation.

The POR_ABC signal received at the logic circuitry 222 from the POR network 220 may be propagated through to logic gate 106K. As long at least one of the POR_ABC signal or the register 214B′ signal is a logic level high (e.g., “1” voltage level), the logic gate 106K outputs a logic high level (e.g., “1” voltage level) to level shifter 224C. The level shifter 224C may generate a POR_BA signal, which may be transmitted to buffer 228B as a disable signal to disable the buffer 228B (e.g., stopping signals from crossing into adjacent power domain). In response to the POR_BA signal from the buffer 228B, circuitry 226A may undergo a power on reset operation. The level shifters 224 and buffers 228 may isolate power operations of power domain 26F and power operations of power domain 26G.

The POR_ABC signal received at the logic circuitry 222 from the POR network 220 may be propagated through to logic gate 106L. As long at least one of the POR_ABC signal or the register 214B′ signal is a logic level high (e.g., “1” voltage level), the logic gate 106M outputs a logic high level (e.g., “1” voltage level) to level shifter 224E. The level shifter 224E may generate a POR_BC signal, which may be transmitted to buffer 228C as a disable signal to disable the buffer 228C (e.g., stopping signals from crossing into adjacent power domain). In response to the POR_BC signal from the buffer 228C, circuitry 226C may undergo a power on reset operation.

The POR_ABC signal received at the logic circuitry 222 from the POR network 220 may be propagated through to logic gate 106M. As long at least one of the POR_ABC signal or the register 214C′ signal is a logic level high (e.g., “1” voltage level), the logic gate 106M outputs a logic high level (e.g., “1” voltage level) to level shifter 224F. The level shifter 224F may generate a POR_CB signal, which may be transmitted to buffer 228D as a disable signal to disable the buffer 228D (e.g., stopping signals from crossing into adjacent power domain). In response to the POR_CB signal from the buffer 228D, circuitry 226B may undergo a power on reset operation. The level shifters 224 and buffers 228 may isolate power operations of power domain 26G, power operations of power domain 26F, and power operations of power domain 26H.

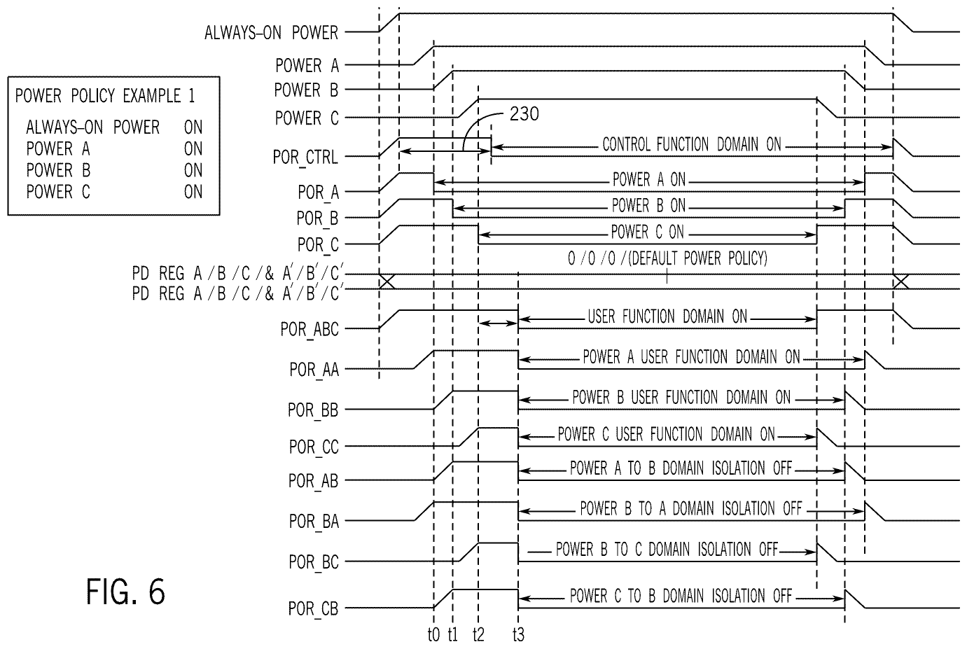

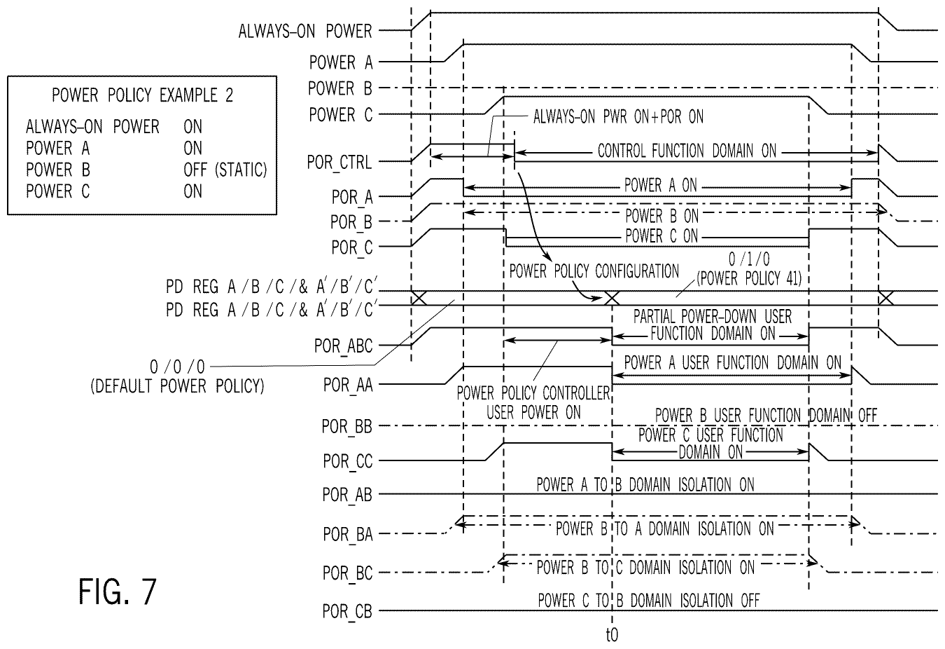

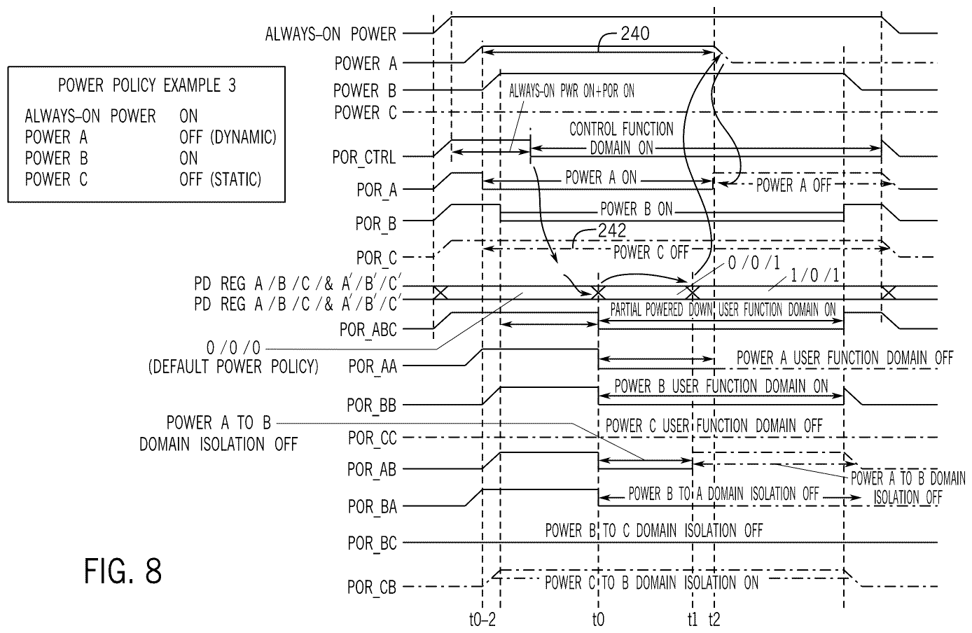

To help elaborate on power policies, FIGS. 6-8 are timing diagrams that respectively illustrate three example power policies. FIG. 6 illustrates a timing diagram example of the default power policy, with each register 214 and register 214′ storing logic low data (e.g., “0” voltage level”) to indicate the power policy. FIG. 7 illustrates a timing diagram example of a modified default policy where power to power domain 26F is on, power to power domain 26G is static off, and power to power domain 26H is on. FIG. 8 illustrates a timing diagram example of a modified policy where power to power domain 26F is dynamic off, power to power domain 26G is on, and power to power domain 26H is static off. For ease of explanation, FIGS. 6-8 are described together herein.

“Always-on power” signal corresponds to voltage supplied from the always-on power supply 204. “Power A” signal corresponds to voltage supplied from the power supply 206A. “Power B” signal corresponds to voltage supplied from the power supply 206B. “Power C” signal corresponds to voltage supplied from the power supply 206C. “POR_CTRL” signal corresponds to voltage generated POR detector 202A and transmitted via path 212 to configuration control circuitry 210. “POR_A” signal corresponds to voltage generated by POR detector 202B based on one or more inputs received via the paths 208 (e.g., input via path 208A to sense power supply 206A) and transmitted to the logic gate 106F. “POR_B” signal corresponds to voltage generated by POR detector 202B based on one or more inputs received via the paths 208 (e.g., input via path 208B to sense power supply 206B) and transmitted to the logic gate 106G. “POR_C” signal corresponds to voltage generated by POR detector 202B based on one or more inputs received via the paths 208 (e.g., input via path 208C to sense power supply 206C) and transmitted to the logic gate 106H. “POR_ABC” signal corresponds to a voltage generated by logic gate 106I based on inputs received from logic gates 106F, 106G, 106H. “POR_AA” signal, “POR_BB” signal, “POR_CC” signal, refer to voltages that control whether the corresponding user function power domains 26F, 26G, 26H are on, respectively. “POR_AB” signal, “POR_BA” signal, “POR_CB” signal, “POR_BC” signal, refer to voltages that control domain isolation between user function power domains 26F, 26G, 26H.

“PD Reg A/B/C & A′/B′/C′” refers to voltages stored as the power policy in the registers 214 and 214′. The configuration control circuitry 210 programs different values into the registers 214 and 214′ to operate the integrated circuit system 12 according to different power policies, as illustrated in FIGS. 6-8. For example, FIG. 6 illustrates a default power policy case where each register is programmed with a logic low data bit (e.g., 000 000, following the convention of register 214 then register 214′ for purposes of discussion). FIG. 7 illustrates a case where a power policy is programmed by configuration control circuitry 210 at time, t0, to be a first example power policy (e.g., 010 010) where registers 214B and 214B′ are programmed with a logic high data bit (e.g., “1” voltage level) and the remaining registers 214 are programmed with a logic low data bit (e.g., “0” voltage level). FIG. 8 illustrates a case where a power policy is programmed by configuration control circuitry 210 at a first time, t0, to be a second example power policy and at a second time, t1, to be a third example power policy. The second example power policy may be (e.g., 001 001) where registers 214A and 214A′ are programmed with a logic high data bit (e.g., “1” voltage level) and the remaining registers 214 are programmed with a logic low data bit (e.g., “0” voltage level). The third example power policy may be (e.g., 101 101) where registers 214A, 214A′, 214C, and 214C′ are programmed with a logic high data bit (e.g., “1” voltage level) and the remaining registers 214B and 214B′ are programmed with a logic low data bit (e.g., “0” voltage level).

Referring now to FIG. 6, in the default case, the POR_CTRL signal may be generated in response to the always-on power supply 204 being powered. The POR detector 202B may experience a delay indicated by time period 230 between receiving the always-on power signal and generating the POR_CTRL signal.

The POR detector 202B may generate the POR_A signal in response to the power A signal via path 208A reaching a threshold voltage level, such as occurs at t0. The POR detector 202B may generate the POR_B signal in response to the power B signal via path 208B reaching a threshold voltage level, such as occurs at t1. The POR detector 202B may generate the POR_C signal in response to the power C signal via path 208C reaching a threshold voltage level, such as occurs at t2. The POR_A signal, POR_B signal, and POR_C signal are merged at logic circuitry 216 based on voltages stored in registers 214 to generate POR_ABC signal at t3 as an active high voltage (e.g., logic level high corresponding reset being active or power domain not being on).

The POR_ABC signal is merged at logic circuitry 222 based on voltages stored in registers 214′ to generate respective of POR_AA signal, POR_BB signal, POR_CC signal, POR_AB signal, POR_BA signal, POR_BC signal, POR_CB signal to indicate that the power domains 26F, 26G, and 26H are powered and to isolate between the power domains 26F, 26G, and 26H.

As noted earlier, comparing FIGS. 6 and 7, registers 214 and 214′ are programmed at t0 in FIG. 7 with a different power policy (e.g., 010 010). This programming occurs in response to the configuration control circuitry 210 determining that power B power supply 206B is not supplying power to power domain 26G to disable the power domain 26G via registers 214 and 214′. Since power B power supply 206B is off, power B signal remains a logic low in FIG. 7, POR_B signal is generated as a logic high (e.g., “1” voltage level) by the POR detector 202B, and the power policy stored in 214 and 214′ is updated to reflect this. Downstream, since POR_BB signal, POR_BA signal, and POR_BC signals are generated based on data stored in registers 214B and 214B', the signals are set to signal that power domain 26G is off and to turn on domain isolation between power domains 26F and 26G and between power domains 26G and 26H.

In FIG. 8, power supply 206A is operated to change supplied voltage, which causes power A signal to change in value at a first time, t0-2, and at a second time, t2. During time period 240, while power supply 206A is supplying a threshold voltage level, the POR detector 202B detects such supply and corresponds by generating the POR_A signal (as an active low signal) indicating that power supply A is on for that time period. However, after the time period 240, the POR detector 202B changes the state of the POR_A signal to indicate that the power supply 206A is off after t2. Although the power supply 206A is dynamic in its supply of voltage, power supply 206C may be a static off and for the time period 242 cause the POR_C signal to be generated as a logic high signal (e.g., “1” voltage level) signaling that the power supply 206C is off. While the power supplies 206A and 206B are on and the power supply 206C is off, registers 214 and 214′ may be programmed with power policy of 001 001 by the control configuration circuitry 110. While the power supply 206A is off, the power supply 206B is on, and the power supply 206C is off, registers 214 and 214′ are programmed with power policy of 101 101. Doing so enables suitable inter-power domain isolation and power supply status signaling to propagate to downstream circuitry via respective of activation and deactivation signals, POR_AA signal, POR_BB signal, POR_CC signal, POR_AB signal, POR_BA signal, POR_BC signal, and POR_CB signal.

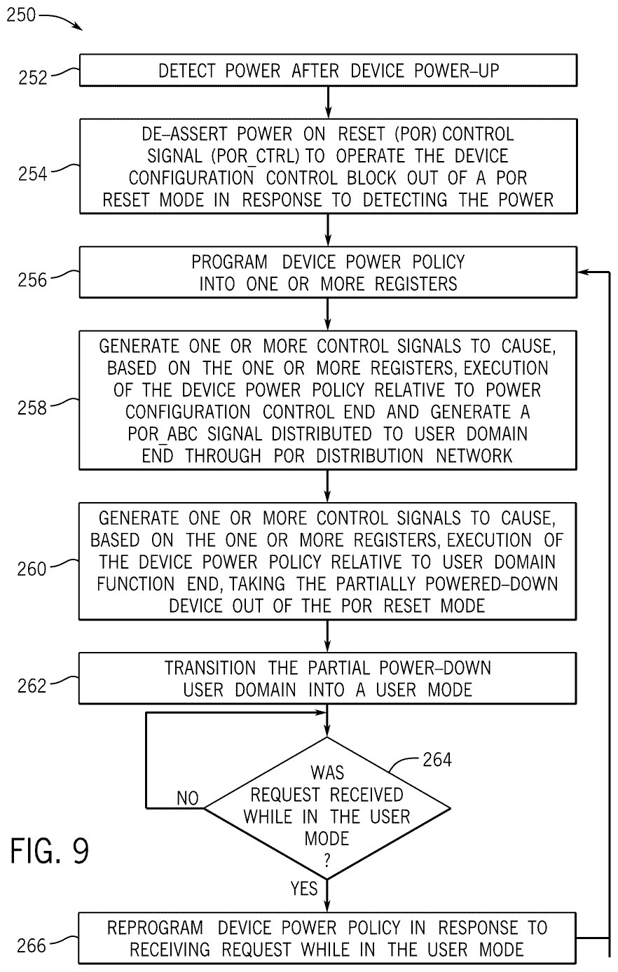

FIG. 9 is a flow chart of a process 250 of operating the integrated circuit system 12 of FIGS. 3 and/or 5 according to stored power policies of register 214 and 214'. Although described herein as performed by control circuitry 200, it should be understood that other processing circuitry and/or logic circuitry may perform one or more operations described herein. For example, SDM 72 may perform some or all of the operations of the process 250. Certain operations are described herein relative to process 250 and it should be understood that some systems may include additional or alternative operations to implement the operations described herein.

At block 252, the control circuitry 200 may detect power after device power up. The POR detector 202A may detect the power based on a voltage received from a power supply. For example, the power supply supplying the voltage used for device power detection may be the always-on power supply 204. The always-on power supply 204 may not be power-gated during normal operation and/or may be power-gated but may not have power removed during power gating operations. In this way, the always-on power supply 204 supplies at least some amount of electrical signal during operation and does not supply an electrical signal while the integrated circuit system 12 is removed from power.

At block 254, the control circuitry 200 may de-assert POR_CTRL signal to operate the device configuration control block out of a POR reset mode in response to detecting the power. The POR_CTRL signal may be an active high signal, as illustrated and discussed relative to FIG. 6. For example, the POR detector 202A of the control circuitry 200 may generate and transmit the POR_CTRL internally to the configuration control circuitry 210 of the control circuitry 200, which may control configuration of registers 214 and 214′ based on the POR_CTRL signal.

At block 256, the control circuitry 200 may program device power policy into one or more registers. The one or more registers may facilitate control of power and isolation operations. The one or more registers may include registers 214 and 214′. The configuration control circuitry 210 of the control circuitry 200 may program the registers 214 and 214′. For example, the configuration control circuitry 210 may configure the registers (e.g., registers 214 and 214′) via a CNOC or other suitable communication interface, such as joint test action group protocol (JTAG) compatible signaling methods or other firmware compatible signaling methods.

At block 258, the control circuitry 200 may generate one or more control signals to cause, based on the one or more registers (e.g., registers 214 and 214′), execution of the device power policy relative to power configuration control end and generate a POR_ABC signal distributed to user domain end through POR distribution network (e.g., POR network 220). The control circuitry 200 may generate the control signals based on operations of its POR detector 202B. The one or more control signals may include POR_A signal, POR_B signal, and POR_C signal. The POR_ABC signal may merge POR_A signal, POR_B signal, and POR_C signal into one bit based on logic circuitry 216 of FIG. 5.

At block 260, the integrated circuit system 12 may generate one or more control signals to cause, based on the one or more registers (e.g., registers 214 and 214′), execution of the device power policy relative to user domain function end (e.g., power domain 26B), taking the partially powered-down integrated circuit system 12 out of the POR reset mode. The POR reset mode may be used for configuration and power isolations. The one or more control signals may include POR_AA signal, POR_BB signal, POR_CC signal, POR_AB signal, POR_BA signal, POR_BC signal, POR_CB signal to indicate that the power domains 26F, 26G, and 26H are powered and to isolate between the power domains 26F, 26G, and 26H. These signals may be generated based on logic circuitry 222. The one or more control signals disable and isolate a power domain 26, or enable and intercouple a power domain 26, relative to adjacent power domains 26.

Based on the power domains 26F, 26G, and/or 26H being powered, the integrated circuit system 12 may transition into a user mode, where configurations may be loaded into the registers (e.g., registers 214 and 214′) to implement power policies per user designs. At block 262, the integrated circuit system 12 is transitioned into a user mode. Circuitry 226 disposed in power domains 26F, 26G, and/or 26H may operate in response to the POR_AA signal, the POR_BB signal, the POR_CC signal, the POR_AB signal, the POR_BA signal, the POR_BC signal, and/or the POR_CB signal to transition itself into the user mode. For example, in response to receiving the signal POR_AA signal, the circuitry 226A may operate according to user configurations (e.g., intellectual property (IP) core) loaded into its FPGA core 82 programmable logic circuitry.

At block 264, the control circuitry 200 may poll to identify whether a power policy change request is received while the integrated circuit system 12 is operated in the user mode. The polling may be repeated until a request is received, such as at a repeated frequency over time. In response to the power policy change request being received while in the user mode, at block 266, the control circuitry 200 may reprogram device power policy in response to receiving the request while in the user mode. To reprogram, the integrated circuit system 12 may load the power policy received into the registers (e.g., registers 214 and 214′) to implement the requested power policy. This may trigger the downstream components to update and implement the changes accordingly and as described herein. For example, if the request indicates a power policy of 010 010, the subsequent operations performed between blocks 256 and 264, where polling is repeated parallel to ongoing processing operations, may correspond to operations of FIG. 7 that implement the example power policy of 010 010.

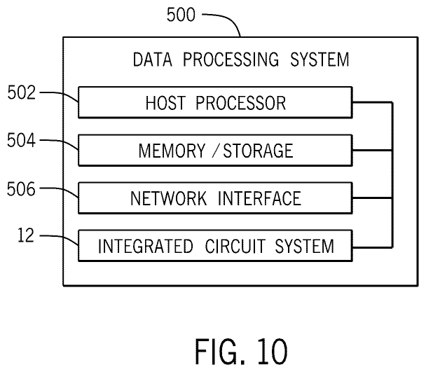

The systems and methods described herein may be applied with other types of integrated circuit systems. For example, the multi-die POR management architecture described herein may be used with central processing units (CPUs), graphics cards, hard drives, or other components. For example, the circuits discussed above may be implemented on the integrated circuit system 12, which may be a component included in a data processing system, such as a data processing system 500, shown in FIG. 10. The data processing system 500 may include the integrated circuit system 12 (e.g., a programmable logic device), a host processor 502, memory and/or storage circuitry 504, and a network interface 506. The data processing system 500 may include more or fewer components (e.g., electronic display, user interface structures, application specific integrated circuits (ASICs)). Moreover, any of the circuit components depicted in FIG. 10 may include the integrated circuit system 12. The host processor 502 may include any of the foregoing processors that may manage a data processing request for the data processing system 500 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 504 may include random access memory (RAM), read-only memory (ROM), one or more hard drives, flash memory, or the like. The memory and/or storage circuitry 504 may hold data to be processed by the data processing system 500. In some cases, the memory and/or storage circuitry 504 may also store configuration programs (e.g., bitstreams, mapping function) for programming the integrated circuit system 12. The network interface 506 may allow the data processing system 500 to communicate with other electronic devices. The data processing system 500 may include several different packages or may be contained within a single package on a single package substrate. For example, components of the data processing system 500 may be located on several different packages at one location (e.g., a data center) or multiple locations. For instance, components of the data processing system 500 may be located in separate geographic locations or areas, such as cities, states, or countries.

The data processing system 500 may be part of a data center that processes a variety of different requests. For instance, the data processing system 500 may receive a data processing request via the network interface 506 to perform encryption, decryption, machine learning, video processing, voice recognition, image recognition, data compression, database search ranking, bioinformatics, network security pattern identification, spatial navigation, digital signal processing, or other specialized tasks.

It is noted that the above-described architecture may be used with multi-die integrated devices, multi-power domain integrated devices, multi-die and multi-power domain integrated devices, a 2.5D integrated FPGA, a 3D integrated FPGA, a FPGA with mixed disaggregated die, 2.5D multi-die integration, a 3D multi-die integration, a monolithic FPGA with distributed POR power detection, or the like.

Described herein may be a power-on reset (POR) structure as applied to a multi-power domain and/or a multi-die integrated device. The structure may enable modular and self-contained POR detection per die. The structure may centralize POR control on one die (e.g., die 70A or another main die). The structure may enable die-to-die connections with merge logic and weak-pull terminations in each die. The structures defined herein may be a relatively low complexity, relatively high scalability, “plug-and-play” design that is able to be deployed in integrated circuits without custom integrated circuit-specific design and/or may be deployed through leveraging existing circuitry of an integrated circuit.

Systems and methods described herein may be applied to a 2.5D FPGA system. The 2.5D FPGA system may involve multiple heterogenous dies integrating with FPGA die(s) through one or more interposers with modular and self-contained POR detection per die containing different subsystems. These die may include a high speed serial interface (HSSI) die, high bandwidth memory (HBM) die, an analog die, a die in an active interposer, or the like.

Systems and methods described herein may be applied to a 3D FPGA system. The 3D FPGA system may involve multiple heterogenous dies integrating with FPGA die(s) through vertical stacking and Through-Silicon-Via (TSV) with modular and self-contained POR detection per die containing different subsystems. These die may include a high voltage input/output (HVIO) die, a static random access memory (SRAM) and/or a dynamic random access memory (DRAM) die, a power management die, or the like.

Systems and methods described herein may be applied to a monolithic FPGA. For example, the systems and methods may be applied to a monolithic FPGA having subsystems with centralized POR detection and control in one or more subsystems. Another Monolithic FPGA may include subsystems with distributed POR detection per SS and centralized POR control in one subsystem. As another example, a subsystem-to-subsystem POR connection may be used with merge logic and weak pull termination in another monolithic FPGA, which may include a CNOC bus with merge logic built in CNOC router, a customized path with merge logic built in the path, and/or weak pull up/down termination value set for correct standalone die operation.

Systems and methods described herein also include a configurable structure to support partial power-down in an integrated device that may include the following a power domain (e.g., power island partition) able to be powered down, circuitry that sets device power-down intention (e.g., power policy), and a POR system that executes the device power-down intention.

Systems and methods described herein may also include a configuration flow, which may include a device initialization control program and an FPGA development software to generate and program a device configuration file into the integrated circuit as an FPGA. The device configuration file may include device power-down intention (e.g., power policy) declarations.

Technical effects of the present application include systems and methods that enable a power on reset system for a disaggregated die (DD) device based on a power on reset (POR) detection circuitry that detects respective power statuses of the different die. The detected result of each die may be logically merged and propagated through a CNOC or other shared communication bus to a main die of the DD device, where the main die may control the device-wide configuration or operation of the DD device based on the merged signal. DD devices may use POR operations for device configuration control upon device power-up and for maintaining device safety in user mode and during power-down. As described herein, integrated circuitry described herein enables each die to have its own POR information for a standalone die test (with suitable isolation to do so) and enables each die to function as one, whole FPGA core with a single POR after the multi-die integration, which may end once POR ends and the POR_FPGA_int signal is generated. As discussed herein, integrated circuit may detect a state of each power supply of each domain and enable initialization and configuration in response to the power supplies being powered at a threshold voltage level. The integrated circuit may continue to monitor the power supplies. If a power supply is removed, control circuitry may set the integrated circuit to a reset mode. These and other technical improvements may occur based on the systems and methods described herein.

While the embodiments set forth in the present disclosure may be susceptible to various modifications and alternative forms, specific embodiments have been shown by way of example in the drawings and have been described in detail herein. However, the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function]...” or “step for [perform]ing [a function]...”, it is intended that such elements are to be interpreted under 35 U.S.C. 112(f). However, for any claims containing elements designated in any other manner, it is intended that such elements are not to be interpreted under 35 U.S.C. 112(f).

### Example Embodiments

Example embodiments of the disclosure may include, among other things:
EXAMPLE EMBODIMENT 1. An integrated circuit device comprising: a first die configured to generate a first power status signal; a second die configured to generate a second power status signal; and a bus coupling the first die and the second die, wherein the bus comprises: merge circuitry that waits to send the second power status signal to the first die until receiving the first power status signal from the first die; and bus termination circuitry that couples the bus to ground.
EXAMPLE EMBODIMENT 2. The integrated circuit device of example embodiment 1, comprising a plurality of daughter die that includes the second die, wherein the first die corresponds to main die, and wherein the first die is coupled to each daughter die of the plurality of daughter die through the bus.
EXAMPLE EMBODIMENT 3. The integrated circuit device of example embodiment 2, wherein the merge circuitry is configured to wait to send the second power status signal to the first die until after the bus has received respective power status signals from each of the plurality of daughter die.
EXAMPLE EMBODIMENT 4. The integrated circuit device of example embodiment 3, wherein a last die of the plurality of daughter die comprises the bus termination circuitry.
EXAMPLE EMBODIMENT 5. The integrated circuit device of example embodiment 1, wherein the merge circuitry comprises a plurality of OR logic gates.
EXAMPLE EMBODIMENT 6. The integrated circuit device of example embodiment 1, wherein the first die comprises secure device management circuitry configured to generate the first power status signal, wherein the second die comprises remote device management circuitry configured to generate the second power status signal, and wherein the bus is coupled to the first die via the secure device management circuitry and to the second die via the remote device management circuitry.
EXAMPLE EMBODIMENT 7. The integrated circuit device of example embodiment 6, wherein the secure device management circuitry is configured to program a plurality of registers with a power policy.
EXAMPLE EMBODIMENT 8. The integrated circuit device of example embodiment 1, comprising a third die disposed in a first power domain, wherein the second die is disposed in a second power domain, and wherein one or more buffers couple the first power domain to the second power domain.
EXAMPLE EMBODIMENT 9. The integrated circuit device of example embodiment 8, wherein the one or more buffers are selectively disabled based on a power policy to isolate the first power domain from the second power domain.
EXAMPLE EMBODIMENT 10. A device comprising: a first power domain comprising: a power on reset detector configured to generate a control signal based on power supplied to the first power domain; a plurality of registers; and configuration control circuitry configured to write a power policy to the plurality registers in response to the control signal; and a second power domain comprising programmable logic configured to: receive a user configuration for implementation in the programmable logic; and perform one or more operations of the user configuration based on the power policy of the plurality of registers.
EXAMPLE EMBODIMENT 11. The device of example embodiment 10, comprising a third power domain and a plurality of buffers disposed between the second power domain and the third power domain.
EXAMPLE EMBODIMENT 12. The device of example embodiment 11, wherein the plurality of buffers isolate the second power domain from the third power domain while the second power domain is powered off.
EXAMPLE EMBODIMENT 13. The device of example embodiment 10, wherein the programmable logic is configured to perform the one or more operations based on the power policy being read from the plurality of registers and being merged with one or more power on signals indicating that the second power domain is powered.
EXAMPLE EMBODIMENT 14. The device of example embodiment 13, wherein the first power domain comprises a power on reset detector configured to generate the one or more power on signals based on a bus interconnecting the first power domain, the second power domain, and a plurality of other power domains, wherein the bus merges respective power on signals during propagation to condense a plurality of power on signals into one bit.
EXAMPLE EMBODIMENT 15. A method comprising: detecting power after an integrated circuit is powered; de-asserting a power on reset (POR) control signal (POR_CTRL); programming a power policy into one or more registers based on the POR_CTRL; and generate one or more control signals to cause, based on reading the power policy from the one or more registers, execution of the power policy relative to a user power domain.
EXAMPLE EMBODIMENT 16. The method of example embodiment 15, comprising: receiving one or more power on signals from one or more power domains of the user power domain, wherein a first power on signal of the one or more power on signals indicates that a corresponding power domain is powered to a threshold voltage; and generating the one or more control signals in response to the one or more power on signals.
EXAMPLE EMBODIMENT 17. The method of example embodiment 15, comprising: transitioning the user power domain from a power on reset mode to a user mode; and polling a bus to determine whether a request with an additional power policy was received via the bus.
EXAMPLE EMBODIMENT 18. The method of example embodiment 17, comprising: reprograming the one or more registers with the additional power policy in response to determining that the request was received; and generating one or more additional control signals to cause, based on reading the power policy from the one or more registers, execution of the additional power policy relative to the user power domain.
EXAMPLE EMBODIMENT 19. The method of example embodiment 18, wherein the one or more additional control signals comprises activation and deactivation signals in response to the additional power policy indicating that one or more power domains of the user power domain are powered down.
EXAMPLE EMBODIMENT 20. The method of example embodiment 19, comprising generating at least one control signal of the additional control signals that operate one or more buffers to deactivate, wherein the one or more buffers isolate powered down power domains and powered power domains.

What is claimed is:

1. An integrated circuit device comprising:
a first die configured to generate a first power status signal;
a second die configured to generate a second power status signal; and
a bus coupling the first die and the second die, wherein the bus comprises:
merge circuitry that waits to send the second power status signal to the first die until receiving the first power status signal from the first die; and
bus termination circuitry that couples the bus to ground.

2. The integrated circuit device of claim 1, comprising a plurality of daughter die that includes the second die, wherein the first die corresponds to main die, and wherein the first die is coupled to each daughter die of the plurality of daughter die through the bus.

3. The integrated circuit device of claim 2, wherein the merge circuitry is configured to wait to send the second power status signal to the first die until after the bus has received respective power status signals from each of the plurality of daughter die.

4. The integrated circuit device of claim 3, wherein a last die of the plurality of daughter die comprises the bus termination circuitry.

5. The integrated circuit device of claim 1, wherein the merge circuitry comprises a plurality of OR logic gates.

6. The integrated circuit device of claim 1, wherein the first die comprises secure device management circuitry configured to generate the first power status signal, wherein the second die comprises remote device management circuitry configured to generate the second power status signal, and wherein the bus is coupled to the first die via the secure device management circuitry and to the second die via the remote device management circuitry.

7. The integrated circuit device of claim 6, wherein the secure device management circuitry is configured to program a plurality of registers with a power policy.

8. The integrated circuit device of claim 1, comprising a third die disposed in a first power domain, wherein the second die is disposed in a second power domain, and wherein one or more buffers couple the first power domain to the second power domain.

9. The integrated circuit device of claim 8, wherein the one or more buffers are selectively disabled based on a power policy to isolate the first power domain from the second power domain.

10. A device comprising:
a first power domain comprising:
a power on reset detector configured to generate a control signal based on power supplied to the first power domain;
a plurality of registers; and
configuration control circuitry configured to write a power policy to the plurality registers in response to the control signal; and
a second power domain comprising programmable logic configured to:
receive a user configuration for implementation in the programmable logic; and
perform one or more operations of the user configuration based on the power policy of the plurality of registers.

11. The device of claim 10, comprising a third power domain and a plurality of buffers disposed between the second power domain and the third power domain.

12. The device of claim 11, wherein the plurality of buffers isolate the second power domain from the third power domain while the second power domain is powered off.

13. The device of claim 10, wherein the programmable logic is configured to perform the one or more operations based on the power policy being read from the plurality of registers and being merged with one or more power on signals indicating that the second power domain is powered.

14. The device of claim 13, wherein the first power domain comprises a power on reset detector configured to generate the one or more power on signals based on a bus interconnecting the first power domain, the second power domain, and a plurality of other power domains, and wherein the bus merges respective power on signals during propagation to condense a plurality of power on signals into one bit.

15. A method comprising:
detecting power after an integrated circuit is powered;
de-asserting a power on reset (POR) control signal (POR_CTRL);
programming a power policy into one or more registers based on the POR_CTRL; and
generating one or more control signals to cause, based on reading the power policy from the one or more registers, execution of the power policy relative to a user power domain.

16. The method of claim 15, comprising:
receiving one or more power on signals from one or more power domains of the user power domain, wherein a first power on signal of the one or more power on signals indicates that a corresponding power domain is powered to a threshold voltage; and
generating the one or more control signals in response to the one or more power on signals.

17. The method of claim 15, comprising:
transitioning the user power domain from a power on reset mode to a user mode; and
polling a bus to determine whether a request with an additional power policy was received via the bus.

18. The method of claim 17, comprising:
reprograming the one or more registers with the additional power policy in response to determining that the request was received; and
generating one or more additional control signals to cause, based on reading the power policy from the one or more registers, execution of the additional power policy relative to the user power domain.

19. The method of claim 18, wherein the one or more additional control signals comprises activation and deactivation signals in response to the additional power policy indicating that one or more power domains of the user power domain are powered down.

20. The method of claim 19, comprising generating at least one control signal of the additional control signals that operate one or more buffers to deactivate, wherein the one or more buffers isolate powered down power domains and powered power domain.
